(19) United States
(12) Patent Application Publication
(10) Pub. No.: US 2026/0176757 A1
(43) Pub. Date: Jun. 25, 2026

(54) METHOD OF FORMING A THIN FILM

(71) Applicant: ASM IP Holding B.V., Almere (NL)

(72) Inventor: Michael Schmotzer, Chandler, AZ (US)

(21) Appl. No.: 19/424,684

(22) Filed: Dec. 18, 2025

Related U.S. Application Data
(60) Provisional application No. 63/737,871, filed on Dec. 23, 2024.

(51) Int. Cl. C23C 16/455; C23C 16/40

(52) U.S. Cl. CPC C23C 16/45534; C23C 16/403; C23C 16/45553

(57) ABSTRACT

A substrate processing method for forming a thin film includes providing a substrate in a reaction chamber and performing a supercycle of a first metal oxide cycle and a second metal oxide cycle. A ratio of a number of the first metal oxide cycles to a number of second metal oxide cycles in the supercycle may be between 6:1 to 1:2. An atomic ratio of the first metal to the second metal in the doped metal oxide film is 7:1 to 15:1.

### CROSS-REFERENCE TO RELATED APPLICATIONS

This application is a nonprovisional of, and claims priority to and the benefit of, U.S. Provisional Patent Application No. 63/737,871 , filed Dec. 23, 2024 and entitled “METHOD OF FORMING A THIN FILM,” with is hereby incorporated by reference herein.

### FIELD

Examples are described that relate to a method for forming a thin film, as well as a structure comprising the thin film and a substrate processing apparatus for forming the thin film. More particularly, examples of the disclosure relate to a method of forming a metal oxide film using at least two different metal oxide deposition cycles and to an apparatus for forming the thin film.

### BACKGROUND

The scaling of semiconductor devices has led to significant improvements in speed and density of integrated circuits. Semiconductor devices need thin films, including metal oxides, with increasing precise and accurate compositions and thicknesses. However, precision and accuracy of composition and thickness of deposited thin films has proven to be a challenge.

For example, one challenge has been finding suitable methods for forming metal oxide films with desirable properties, such as thickness and resistivity, that also are efficient and repeatable. Further, conventional methods that may produce precise and accurate compositions and thickness may result in longer throughput times.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Examples described herein provide a substrate processing method, substrate processing apparatus, and a structure on a substrate. Various examples of the substrate processing method provide for the deposition of a metal oxide, including doped metal oxides. The methods disclosed herein provide thin films (e.g., metal oxide films and doped metal oxide films) with desired properties, such as specific thicknesses and compositions, with efficient, timesaving, precise and accurate techniques.

According to one or more embodiments, a method for the forming of a metal oxide film is provided. An exemplary method includes providing a substrate in a reaction chamber. An exemplary method can further include performing a supercycle comprising at least one first metal oxide cycle and at least one second metal oxide cycle to form the metal oxide film on the substrate. In an exemplary method, the ratio of a number of the first metal oxide cycles to a number of second metal oxide cycles in the supercycle is between about 6:1 to about 1:2. In some embodiments, the ratio of a number of the first metal oxide cycles to a number of second metal oxide cycles in the supercycle is between about 4:1 and 1:1.75, or between about 3:1 and 1:1.5, or between 2:1 and 1:1.25, or between about 1.5:1 and 1:1. In some embodiments, the supercycle is an atomic layer deposition (ALD) process.

In accordance with examples of one or more embodiments, the first metal oxide cycle includes pulsing a first metal precursor comprising a first metal, and pulsing a first oxidizing reactant. In some embodiments, the first metal oxide cycle includes only one pulse of the first metal precursor and only one pulse of the first oxidizing reactant. In some embodiments, the first metal oxide cycle further includes a step of performing a purge after the step of pulsing a first metal precursor. In some embodiments, the first metal oxide cycle further includes a step of performing a purge immediately after the step of pulsing a first metal precursor. In some embodiments, the first metal oxide cycle further includes a step of performing a purge after the step of pulsing the first oxidizing reactant. In some embodiments, the first metal oxide cycle further includes a step of performing a purge immediately after the step of pulsing the first oxidizing reactant.

In accordance with examples of one or more embodiments, the second metal oxide cycle includes pulsing a second metal precursor and pulsing a second oxidizing reactant. In some embodiments, the second metal oxide cycle further includes a step of performing a purge after the step of pulsing a second metal precursor. In some embodiments, the second metal oxide cycle further includes a step of performing a purge immediately after the step of pulsing a second metal precursor. In some embodiments, the second metal oxide cycle further includes a step of performing a purge after the step of pulsing the second oxidizing reactant. In some embodiments, the second metal oxide cycle further includes a step of performing a purge immediately after the step of pulsing the second oxidizing reactant.

In some embodiments, the first oxidizing precursor differs from the second oxidizing precursor. In some embodiments, the first oxidizing reactant includes at least one of H₂O, an alcohol, ozone, O₂, and hydrogen peroxide. In some embodiments, the second oxidizing reactant includes at least one of H₂O, an alcohol, ozone, O₂, and hydrogen peroxide.

In accordance with exemplary embodiments, a growth rate per cycle of the first metal oxide cycle is greater than a growth rate per cycle of the second metal oxide cycle. In some embodiments, a growth rate per cycle of the first metal oxide cycle is more than 1.5 times greater, or more than 3 times greater, or more than 6 times greater than a growth rate per cycle of the second metal oxide cycle. In some embodiments, a growth rate per cycle of the first metal oxide cycle is between about 1.5 to 15 times greater, or between about 3 to 11 times greater, or between about 7 to 10 times greater than a growth rate per cycle of the second metal oxide cycle.

In some embodiments, the supercycle is repeated a plurality of times until the metal oxide film reaches between about 5 Angstroms and 500 Angstroms, or between about 10 Angstroms and about 100 Angstroms, or between about 10 Angstroms and 30 Angstroms. In some embodiments, a cap layer is formed over the metal oxide film. In some embodiments, the cap layer is a different than the metal oxide film.

In some embodiments, the first metal precursor and the second metal precursor are different. In some embodiments, the first metal precursor and the second metal precursor do not contain the same metal. In some embodiments, the first metal precursor comprises a metalorganic compound or a metal halide. In some embodiments, the second metal precursor comprises a metalorganic compound or a metal halide. In some embodiments, the first metal precursor includes hafnium, tantalum, or tungsten. In some embodiments, the second metal precursor includes silicon, zirconium, or aluminum. In some embodiments, the second metal precursor comprises trimethylaluminum (TMA).

According to one or more embodiments, the metal oxide is a doped metal oxide. A doped metal oxide film may be a metal oxide film of a first metal that is doped with a second metal. The atomic ratio of the first metal to the second metal in the doped metal oxide film is about 7:1 to about 15:1, or between about 8:1 to 12:1, or between about 9:1 to about 10:1.

In accordance with further examples of the disclosure, a device is formed using a method and/or include a structure as described herein.

In accordance with various embodiments of the disclosure, a substrate processing apparatus for forming a doped metal oxide film is provided, the apparatus including: a reaction chamber, a susceptor in the reaction chamber configured to hold a substrate; a first metal precursor source configured to provide a first metal precursor into the reaction chamber; a second metal precursor source configured to provide a second metal precursor into the reaction chamber; first oxidizing reactant source configured to provide a first oxidizing reactant into the reaction chamber; a second oxidizing reactant source configured to provide a second oxidizing reactant into the reaction chamber; and a controller including an addressable storage medium, wherein the controller is configured to control gas flow into the reaction chamber to: perform a supercycle including at least one first metal oxide cycle and at least one second metal oxide cycle, wherein the first metal oxide cycle includes: pulsing a first metal precursor, and pulsing a first oxidizing reactant, wherein the second metal oxide cycle includes: pulsing a second metal precursor, and pulsing a second oxidizing reactant, and wherein a ratio of a number of the first metal oxide cycles to a number of second metal oxide cycles in the supercycle is between 7:1 to 1:2.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

FIG. 1 illustrates a method in accordance with one or more embodiments of the disclosure;

FIG. 2 illustrates a supercycle in accordance with one or more embodiments of the disclosure;

FIG. 3 illustrates an example of a substrate processing apparatus in accordance with one or more examples of the disclosure;

FIG. 4 illustrates an example of a structure that forms part of a device in accordance with one or more examples of the disclosure;

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the plural forms as well, unless the context indicates otherwise. It will be further understood that the terms “includes,” “comprises,” “including,” and/or “comprising” used herein specify the presence of stated features, integers, steps, processes, members, components, and/or groups thereof, but do not preclude the presence or addition of one or more other features, integers, steps, processes, members, components, and/or groups thereof.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under,” “underlying,” or “below” will be construed to be relative concepts.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “structure” can refer to a partially or completely fabricated device structure. By way of examples, a structure can be a substrate or include a substrate with one or more layers and/or features formed thereon.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

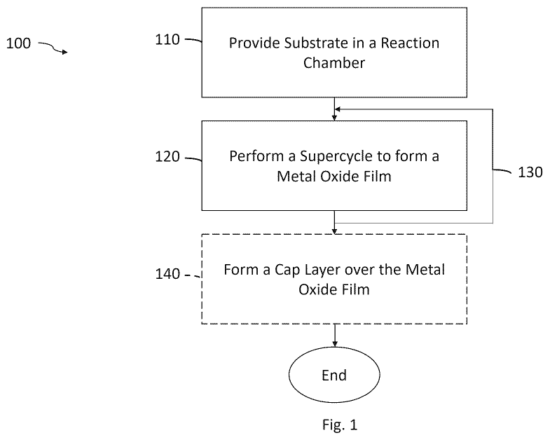

FIG. 1 illustrates a method of forming a thin film on a substrate in accordance with exemplary embodiments of the disclosure.

In some embodiments, the thin film is a metal oxide film. In some embodiments, the metal oxide film is an oxide of a metal, a metalloid (i.e., silicon, boron, tellurium, antimony, germanium, arsenic, or astatine), or a combination of any number of metals and metalloids. In some embodiments, the metal oxide film comprises a metal. In some embodiments, the metal oxide film is an oxide of one or more metals. In some embodiments, the metal oxide film comprises one or more of hafnium, zirconium, or aluminum. In some embodiments, the metal oxide film is a doped metal oxide film. In some embodiments, the doped metal oxide film comprises a first metal, a second metal, and oxygen, wherein the first metal is different from the second metal. In some embodiments, a dopant of a doped metal oxide comprises a metal or silicon. The atomic ratio of the first metal to the second metal in the doped metal oxide film is about 7:1 to about 15:1, or between about 8:1 to 12:1, or between about 9:1 to about 10:1.

Method 100 includes the step of providing a substrate within a reaction chamber (step 110), performing a supercycle to form a metal oxide film (step 120), optionally repeating the step of performing the supercycle (loop 130) and, optionally, forming a cap layer over the metal oxide film (step 140).

During step 110, a substrate is provided into a reaction chamber. In accordance with examples of the disclosure, the reaction chamber can form part of a chemical vapor deposition reactor, such as a chemical vapor deposition (CVD) reactor, an atomic layer deposition (ALD) reactor, or the like. Various steps of methods described herein can be performed within a single reaction chamber or can be performed in multiple reaction chambers, such as reaction chambers of a cluster tool.

During step 110, the substrate can be brought to a desired temperature and/or the reaction chamber can be brought to a desired pressure, such as a temperature and/or pressure suitable for subsequent steps. By way of examples, a temperature (e.g., of a substrate or a substrate support) within a reaction chamber can be between about 0° C. and about 600° C. , or between about 200° C. and about 450° C., or between about 250° C. and about 350° C. By way of examples, a pressure within a reaction chamber can be less than or equal to 100 torr, or less than or equal to 50 torr, or between about 0.1 torr and 50 torr, or between about 0.5 torr and about 5 torr.

During step 120, a supercycle is performed to form a metal oxide film on the substrate. In some embodiments, the supercycle is a cyclical deposition process, such as a cyclic chemical vapor deposition (CCVD), or an atomic layer deposition (ALD) process.

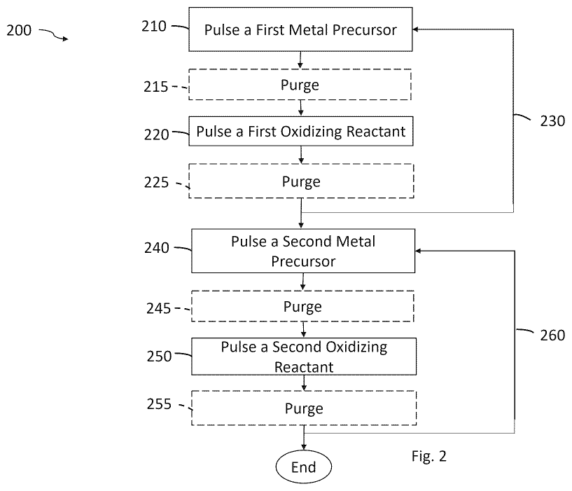

FIG. 2 illustrates a method 200 suitable for step 120 in FIG. 1. Method 200 includes a step of pulsing a first metal precursor 210 to the reaction chamber and a step of pulsing a first oxidizing reactant 220 to the reaction chamber. Method 200 can also include an optional purge step 215 after the step of pulsing a first metal precursor 210 and/or an optional purge step 225 after the step of pulsing a first oxidizing reactant 220. The optional purge steps 215 and 225 may remove gases, precursors, reactants, and/or by-products from the reaction chamber. In some embodiments, the purge steps 215 and 225 are performed immediately after steps 210 and 220, respectively. The first metal oxide cycle comprises the steps 210 and 220, and optionally, purge steps 215 and 225. In some embodiments, the first metal oxide cycle comprises exactly one pulse of the first metal precursor. In some embodiments, the first metal oxide cycle comprises exactly one pulse of the first oxidizing reactant. In some embodiments, the first metal oxide cycle consists of steps 210, 220, and, optionally, 215 and 225. In some embodiments, the first metal oxide cycle can comprise the step 220 performed before the step 210. In some embodiments, the steps 210 and step 220 may at least partially overlap in time. As illustrated, method 200 can include repeating the first metal oxide cycle (loop 230) a desired number of times.

Method 200 continues with a step of pulsing a second metal precursor 240 to the reaction chamber and a step of pulsing a second oxidizing reactant 250 to the reaction chamber. Method 200 can also include an optional purge step 245 after the step of pulsing a second metal precursor 240 and/or an optional purge step 255 after the step of pulsing a second oxidizing reactant 250. The optional purge steps 245 and 255 may remove gases, precursors, reactants, and/or by-products from the reaction chamber. The second metal oxide cycle comprises the steps 240 and 250, and optionally, purge steps 245 and 255. In some embodiments, the second metal oxide cycle comprises exactly one pulse of the first metal precursor. In some embodiments, the second metal oxide cycle comprises exactly one pulse of the first oxidizing reactant. In some embodiments, the second metal oxide cycle can comprise the step 250 performed before the step 240. In some embodiments, the steps 240 and step 250 may at least partially overlap in time. illustrated, method 200 can include repeating the second metal oxide cycle (loop 260) a desired number of times.

In some embodiments, the first and/or second metal precursor comprises a metal, a metalloid (such as silicon), or a combination of any number of metals and metalloids. In some embodiments, the first and/or second metal precursor comprises a metal or a combination of metals. In some embodiments, the first and/or second metal precursor does not comprise a metalloid. In some embodiments, the first metal precursor and the second metal precursor are different. In some embodiments, the first metal precursor and the second metal precursor do not contain the same metal.

In some embodiments, the first oxidizing reactant comprises at least one of H₂O, an alcohol, ozone, O₂, and hydrogen peroxide. In some embodiments, the second oxidizing reactant comprises at least one of H₂O, an alcohol, ozone, O₂, and hydrogen peroxide. In some embodiments, the first oxidizing reactant differs from the second oxidizing reactant. In some embodiments where first oxidizing reactant differs from the second oxidizing reactant, the first oxidizing reactant comprises a different compound than the second oxidizing reactant. In some embodiments where first oxidizing reactant differs from the second oxidizing reactant, the first oxidizing reactant and the second oxidizing reactant comprise at least two compounds, wherein the ratio of the at least two compounds differs in the first oxidizing reactant to the second oxidizing reactant.

Additionally, a carrier and/or inert gas can be co-flowed throughout method 200 or during any of the sub-steps of method 200. By way of example, a carrier and/or an inert gas can be one or more of helium, argon, or nitrogen.

The supercycle 200 comprises at least one first metal oxide cycle and at least one second metal oxide cycle. In some embodiments, the second metal oxide cycle may be performed before the first metal oxide cycle. In some embodiments, the supercycle can comprise a plurality of the first metal oxide cycles and/or the second metal oxide cycles. In such embodiments, the first metal oxide cycles and/or second metal oxide cycles can be performed in any order. In such embodiments, loop 230 and/or loop 260 may be performed after a full first and/or second metal oxide cycle is performed.

The growth rate per cycle of the first metal oxide cycle differs from the growth rate per cycle of the second metal oxide cycle. In some embodiments, the growth rate per cycle of the first metal oxide cycle is greater than the growth rate per cycle of the second metal oxide cycle. In some embodiments, a growth rate per cycle of the first metal oxide cycle is more than 1.5 times greater, or more than 3 times greater, or more than 6 times greater than a growth rate per cycle of the second metal oxide cycle. In some embodiments, a growth rate per cycle of the first metal oxide cycle is between about between about 1.5 to 15 times greater, or between about 3 to 11 times greater, or between about 7 to 10 times greater than a growth rate per cycle of the second metal oxide cycle. In some embodiments, the growth rate per cycle of the first metal oxide cycle is between about 0.5 Angstroms/cycle to about 1.5 Angstroms/cycle, or between about 0.8 Angstroms/cycle to about 1.2 Angstroms/cycle. In some embodiments, the growth rate per cycle of the second metal oxide cycle is between about 0.05 Angstroms/cycle to about 0.5 Angstroms/cycle, or between about 0.1 Angstroms/cycle to about 0.3 Angstroms/cycle.

The ratio of a number of the first metal oxide cycles to a number of second metal oxide cycles in the supercycle is between about 6:1 to about 1:2, or between about 4:1 and 1:1.75, or between about 3:1 and 1:1.5, or between 2:1 and 1:1.25, or between about 1.5:1 and 1:1.

Not to be bound by theory, the ratio of the number of the first metal oxide cycles to a number of second metal oxide cycles depends on the desired thickness and composition of the metal oxide film. The growth rate per supercycle depends on the growth rate per cycle of the first metal oxide cycle and the second metal oxide cycle. As the growth rate per cycle of the first metal oxide cycle differs from the growth rate per cycle of the second metal oxide cycle, the growth rate per supercycle can be fine tuned by controlling both the growth rate per cycle of the first metal oxide cycle and the second metal oxide cycle and the ratio of a number of the first metal oxide cycles to a number of second metal oxide cycles in the supercycle. Further, the use of both the first metal oxide cycle and the second metal oxide cycle will be faster and use less cycles to achieve a specific film thickness. Similarly, a desired composition of a doped metal oxide can be more finely tuned with closer parity to the number of the first metal oxide cycles to a number of second metal oxide cycle.

Returning to FIG. 1, the method 100 may continue with, optionally, repeating the step of performing the supercycle (loop 130). In some embodiments, the supercycle is repeated a plurality of times. In some embodiments, the supercycle is repeated a plurality of times until the doped metal oxide film reaches between about 5 Angstroms and 500 Angstroms, or between about 10 Angstroms and about 100 Angstroms, or between about 10 Angstroms and 30 Angstroms.

It will be appreciated by one with ordinary skill in the art that a growth rate per cycle of the supercycle will be dependent on the growth rates per cycles of the first metal oxide cycle and second metal oxide cycle, as well as ratio of a number of the first metal oxide cycles to a number of second metal oxide cycles in a supercycle. It will also be appreciated by one with ordinary skill in the art that the composition of a doped metal oxide film formed by a supercycle will be dependent on the growth rates per cycles of the first metal oxide cycle and second metal oxide cycle, the choice of the first metal precursor and the second metal precursor, as well as ratio of a number of the first metal oxide cycles to a number of second metal oxide cycles in a supercycle.

Method 100 may continue with, optionally, forming a cap layer over the doped metal oxide film (step 140). In some embodiments, the cap layer is different than the doped metal oxide film. In some embodiments, the cap layer comprises a silicon oxide, a silicon oxynitride, or a silicon nitride.

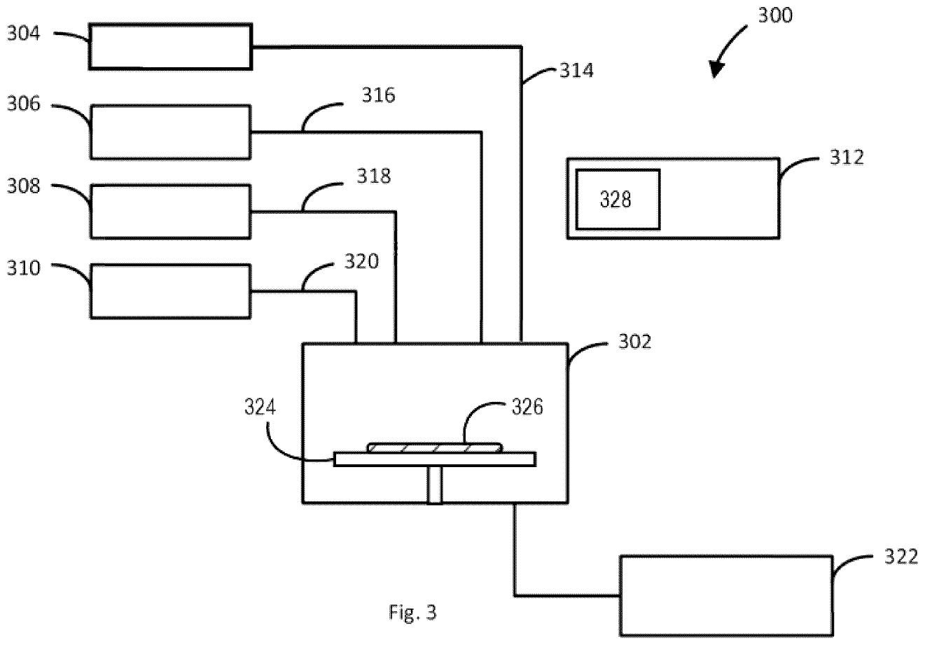

FIG. 3 illustrates an example of a substrate processing apparatus 300 in accordance with one or more examples of the disclosure. Apparatus 300 can be used to perform a method as described herein and/or form a structure or device portion as described herein.

In the illustrated example, apparatus 300 includes one or more reaction chambers 302, a first metal precursor gas source 304, a second metal precursor gas source 306, a first oxidizing reactant gas source 308, a second oxidizing reactant gas source 310, an exhaust source 322, and a controller 312.

Reaction chamber 302 can include any suitable reaction chamber, such as an atomic layer deposition (ALD) or chemical vapor deposition (CVD) reaction chamber.

First metal precursor gas source 304 can include a vessel and one or more metal precursors as described herein-alone or mixed with one or more carrier (e.g., inert) gases. Second metal precursor gas source 306 can include a vessel and one or more metal precursors as described herein-alone or mixed with one or more carrier (e.g., inert) gases. In some embodiments, the first metal precursor and the second metal precursor are different. In some embodiments, the first metal precursor and the second metal precursor do not contain the same metal. First oxidizing reactant gas source 308 can include a vessel and one or more oxidizing reactants as described herein-alone or mixed with one or more carrier gases. Second oxidizing reactant gas source 310 can include one or more oxidizing reactant gases as described herein. Although illustrated with four gas sources 304-310, apparatus 300 can include any suitable number of gas sources. Gas sources 304-310 can be coupled to reaction chamber 302 via lines 314-320, which can each include flow controllers, valves, heaters, and the like.

Exhaust source 322 can include one or more vacuum pumps.

Controller 312 includes electronic circuitry and software to selectively operate valves, manifolds, heaters, pumps, and other components included in the apparatus 300. Such circuitry and components operate to introduce precursors, reactants, and gases from the respective sources 304-310. Controller 312 can control timing of gas pulse sequences, temperature of the substrate and/or reaction chamber, pressure within the reaction chamber, and various other operations to provide proper operation of the apparatus 300. Controller 312 can include control software stored on addressable storage medium 328 to electrically or pneumatically control valves to control flow of precursors, reactants, and purge gases into and out of the reaction chamber 302. Controller 312 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 300 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 302. Further, as a schematic representation of a system, many components have been omitted for simplicity of illustration, and such components may include, for example, various valves, manifolds, purifiers, heaters, containers, vents, and/or bypasses.

During operation of apparatus 300, substrates 326, such as semiconductor wafers, are transferred from, e.g., a substrate handling system to reaction chamber 302 where the substrate 326 is supported on a substrate support, such as susceptor 324. Once substrate(s) are transferred to reaction chamber 302, one or more gases from gas sources 304-310, such as precursors, reactants, carrier gases, and/or purge gases, are introduced into reaction chamber 302.

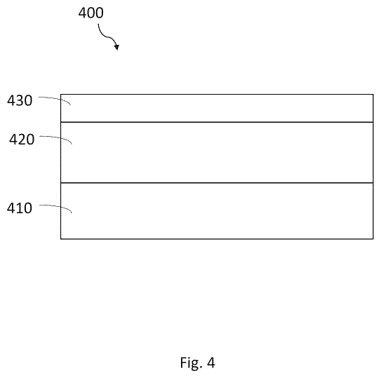

FIG. 4 illustrates a structure/a portion of a device 400 in accordance with additional examples of the disclosure. Device or structure 400 includes a substrate 410 and a film comprising a metal oxide 420. Device or structure 400 may also include a cap layer 430. The metal oxide film 420 may be formed by a method described in this disclosure. The metal oxide film 420 may be a doped metal oxide. The metal oxide film 420 may have a thickness between about 5 Angstroms and 500 Angstroms, or between about 10 Angstroms and about 100 Angstroms, or between about 10 Angstroms and 30 Angstroms. The cap layer 430 may comprise silicon oxide, silicon nitride, or silicon oxynitride.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming a doped metal oxide film, the method comprising:
providing a substrate in a reaction chamber; and
performing a supercycle comprising at least one first metal oxide cycle and at least one second metal oxide cycle to form the doped metal oxide film on the substrate,
wherein the first metal oxide cycle comprises:
pulsing a first metal precursor comprising a first metal, and
pulsing a first oxidizing reactant;
wherein the second metal oxide cycle comprises:
pulsing a second metal precursor comprising a second metal, and
pulsing a second oxidizing reactant;
wherein a ratio of a number of the first metal oxide cycles to a number of second metal oxide cycles in the supercycle is between 6:1 to 1:2,
wherein the first oxidizing reactant differs from the second oxidizing reactant, and
wherein an atomic ratio of the first metal to the second metal in the doped metal oxide film is 7:1 to 15:1.

2. The method of claim 1, wherein performing the supercycle is an atomic layer deposition (ALD) process.

3. The method of claim 1, wherein the supercycle is repeated a plurality of times until the doped metal oxide film reaches between 3 Angstroms and 500 Angstroms.

4. The method of claim 3, further comprising forming a cap layer over the doped metal oxide film, wherein the cap layer is different than the doped metal oxide film.

5. The method of claim 1, wherein the first metal oxide cycle further comprises performing a purge immediately after the step of pulsing the first oxidizing reactant.

6. The method of claim 5, wherein the first metal oxide cycle further comprises performing a purge immediately after the step of pulsing the first metal precursor.

7. The method of claim 6, wherein the second metal oxide cycle further comprises performing a purge immediately after the step of pulsing the second metal precursor, and performing a purge immediately after the step of pulsing the second oxidizing reactant.

8. The method of claim 1, wherein the first oxidizing reactant comprises at least one of H₂O, an alcohol, ozone, O₂, and hydrogen peroxide, and wherein the second oxidizing reactant comprises at least one of H₂O, an alcohol, ozone, O₂, and hydrogen peroxide.

9. The method of claim 1, wherein the first oxidizing reactant comprises at least one of H₂O, an alcohol, and ozone, and wherein the second oxidizing reactant comprises at least one of H₂O, an alcohol, and ozone.

10. The method of claim 1, wherein the first metal precursor and the second metal precursor are different.

11. The method of claim 1, wherein the first metal precursor and the second metal precursor do not contain the same metal.

12. The method of claim 1, wherein a growth rate per cycle of the first metal oxide cycle is more than 1.5 times greater than a growth rate per cycle of the second metal oxide cycle.

13. The method of claim 1, wherein a growth rate per cycle of the first metal oxide cycle is between 1.5 to 10 times greater than a growth rate per cycle of the second metal oxide cycle.

14. The method of claim 1, wherein the ratio of the number of the first metal oxide cycles to the number of second metal oxide cycles in the supercycle is between 2:1 to 1:2.

15. The method of claim 1, wherein the first metal precursor comprises hafnium.

16. The method of claim 1, wherein the second metal precursor comprises trimethylaluminum (TMA).

17. A method for forming a doped metal oxide film, the method comprising:
providing a substrate in a reaction chamber; and
performing a supercycle comprising of at least one first metal oxide cycle and at least one second metal oxide cycle to form the doped metal oxide film on the substrate,
wherein the first metal oxide cycle has a first growth rate per cycle,
wherein the second metal oxide cycle has a second growth rate per cycle,
wherein the first growth rate per cycle is 1.5 to 10 times greater than the second growth rate per cycle,
wherein the ratio of a number of the first metal oxide cycles to a number of second metal oxide cycles in the supercycle is between 7:1 to 1:2, and
wherein the atomic ratio of a first metal to a second metal in the doped metal oxide film is 6:1 to 15:1.

18. The method of claim 17, wherein the first growth rate per cycle is 3 to 8 times greater than the second growth rate per cycle.

19. The method of claim 17, wherein the ratio of the number of the first metal oxide cycles to the number of the second metal oxide cycles in the supercycle is between 2:1 to 1:2.

20. A substrate processing apparatus for forming a doped metal oxide film, the apparatus comprising:
a reaction chamber;
a susceptor in the reaction chamber configured to hold a substrate;
a first metal precursor source configured to provide a first metal precursor into the reaction chamber;
a second metal precursor source configured to provide a second metal precursor into the reaction chamber;
a first oxidizing reactant source configured to provide a first oxidizing reactant into the reaction chamber;
a second oxidizing reactant source configured to provide a second oxidizing reactant into the reaction chamber; and
a controller comprising an addressable storage medium, wherein the controller is configured to control gas flow into the reaction chamber to:
perform a supercycle comprising at least one first metal oxide cycle and at least one second metal oxide cycle,
wherein the first metal oxide cycle comprises:
pulsing the first metal precursor, and
pulsing the first oxidizing reactant,
wherein the second metal oxide cycle comprises:
pulsing the second metal precursor, and
pulsing the second oxidizing reactant,
wherein a ratio of a number of the first metal oxide cycles to a number of second metal oxide cycles in the supercycle is between 7:1 to 1:2.
